(19) United States
(12) Patent Application Publication
(10) Pub. No.: US 2013/0298447 A1
(43) Pub. Date: Nov. 14, 2013

(54) CHASSIS HAVING BUG KILLING PROPERTY FOR ELECTRONIC DEVICE

(71) Applicants: HONG FU JIN PRECISION INDUSTRY (ShenZhen) CO., LTD., (US); HON HAI PRECISION INDUSTRY CO., LTD., New Taipei (TW)

(72) Inventor: QIANG CHEN, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/757,974

(22) Filed: Feb. 4, 2013

(30) Foreign Application Priority Data
May 9, 2012 (CN) 201210141056.X

(51) Int. Cl. A01M 1/06; H05K 5/02

(52) U.S. Cl. CPC A01M 1/06; H05K 5/0213
USPC 43/139

(57) ABSTRACT

A chassis having a bug attracting and killing property includes a housing, a heat dispersing fan fastened in the housing, and a bug killing assembly located in the chassis. The bug killing assembly includes a body which defines a cavity, and a bug catching net positioned in the cavity. The heat dispersing fan pulls air into the cavity to form airflow. The airflow sucks bugs into the cavity to be caught by the bug catching net.

### BACKGROUND

1. Technical Field

The present disclosure generally relates to chassis for electronic devices, especially to a chassis having bug killing property for an electronic device.

2. Description of Related Art

When using electronic devices (such as computers) in summer, users often suffer bites from bugs (such as mosquitoes), which makes the users feel uncomfortable. So, the users may use electric mosquito repellent to dispel the bugs. However, electric mosquito repellent can produce harmful gases.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is a schematic view of a chassis in accordance with an exemplary embodiment, the chassis includes a housing, a heat dispersing fan, and a bug killing assembly.

FIG. 2 is a schematic view of the chassis shown in FIG. 1 with a door of the bug killing assembly opened.

FIG. 3 is a schematic view of the bug killing assembly shown in FIG. 1 with a side board removed.

FIG. 4 is a schematic view of the bug killing assembly of FIG. 1 mounted with a bug sucking fan for sucking in bugs.

FIG. 5 is a partial exploded view of the chassis of FIG. 4.

### DETAILED DESCRIPTION

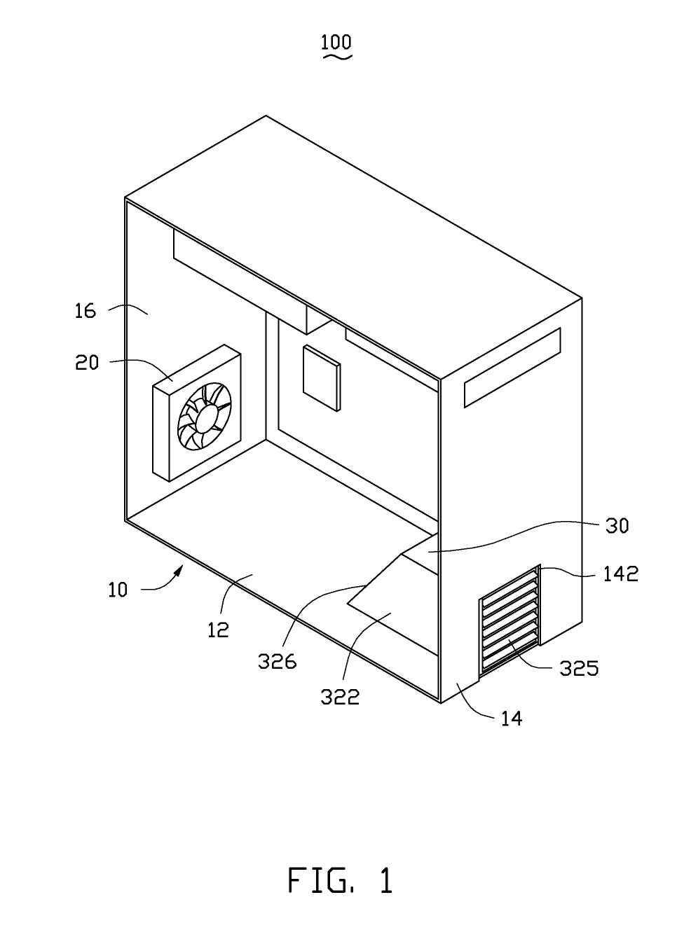

FIG. 1 shows a chassis 100 which can be applied to electronic devices, such as computers and servers.

The chassis 100 includes a housing 10, a heat dispersing fan 20, and a bug killing assembly 30.

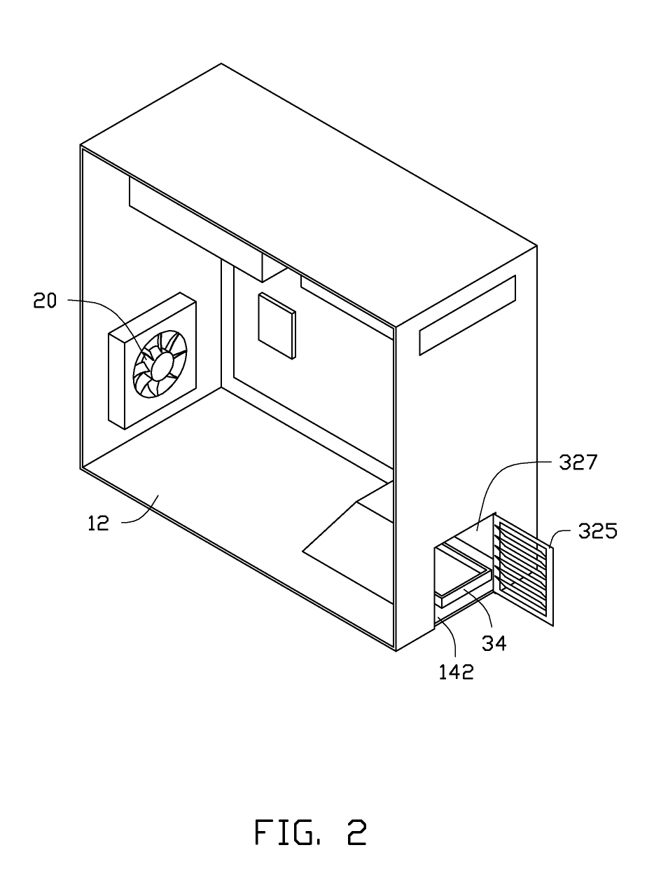

Also referring to FIG. 2, the housing 10 includes a bottom plate 12, a front plate 14, and a back plate 16. The front plate 14 and the back plate 16 are positioned at the two ends of the bottom plate 12 and face each other. The front plate 14 defines a passage 142.

The heat dispersing fan 20 is for pulling in outside air into the chassis 100 through the passage 142 to form an airflow. The airflow cools the electronic elements (not shown) of the chassis 100, and also pulls in bugs into the chassis 100 through the passage 142. In the embodiment, the heat dispersing fan 20 is fastened on the back plate 16 and faces the passage 142.

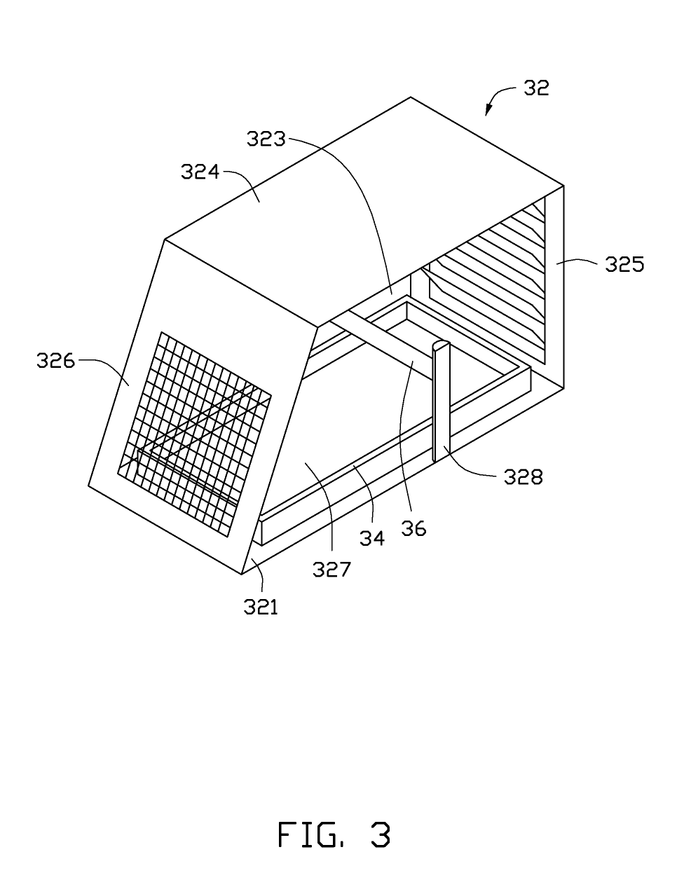

Also referring to FIG. 3, the bug killing assembly 30 includes a body 32, a drawer box 34, and an ultraviolet tube 36.

The body 32 includes a base board 321, a first side board 322, a second side board 323, a top board 324, a door 325, and a bug catching net 326.

The base board 321 is fastened on the bottom plate 12 of the housing 10. The first side board 322 and the second side board 323 are positioned at the two sides of the base board 321 and face each other. The top board 324 connects the ends of the first side board 322 and the second side board 323 away from the base board 321. As such, the base board 321, the first side board 322, the second side board 323, and the top board 324 together define a cavity 327.

The door 325 shields the passage 142. In the embodiment, the door 325 is a louvered door. Thus, even when the door 325 is closed, air can still pass through the passage 142 to the cavity 327. The door 325 is rotatably fastened to the second side board 323 to open/close the passage 142.

The bug catching net 326 is made of metal. The bug catching net 326 connects the top board 324 and the base board 321, and is inclined towards the door 325. When bugs are pulled into the cavity 327, the bugs will be caught by the bug catching net 326.

The drawer box 34 is for collecting dead bugs. When the bugs are killed by the bug catching net 326, the dead bugs fall into the drawer box 34. In the embodiment, the drawer box 34 is located in the cavity 327 and positioned on the base board 321.

The ultraviolet tube 36 emits ultraviolet light to further attract bugs into the cavity 327. In the embodiment, the ultraviolet tube 36 is fastened upon the drawer box 34 by two fixing blocks 328 secured on the base board 321.

In assembly, the door 325 is first opened, the drawer box 34 is positioned on the base board 321. The door 325 is closed, the base board 321 is fastened on the bottom plate 12 and the passage 142 and the cavity 327 are enclosed by the door 325. The heat dispersing fan 20 is fastened on the back plate 16. As such, the chassis 100 is finished.

In use, the heat dispersing fan 20 is turned on to pull air into the cavity 327 through the passage 142. The air forms airflow in the cavity 327, gathering bugs around the passage 142 into the cavity 327. Simultaneously, the ultraviolet tube 36 also emits ultraviolet light to also attract bugs into the cavity 327. The bugs are then blown onto the bug catching net 326 by the airflow. Because the temperature inside the chassis 100 is about 38° C. to about 40° C., the bugs will be dehydrated leading to death in about 3-5 minutes on the bug catching net 326. Once the heat dispersing fan 20 is turned off, the airflow in the chassis 100 disappears, and the dead bugs fall down to the drawer box 34. Then, the door 325 is opened to remove the drawer box 34 to pull out the dead bugs.

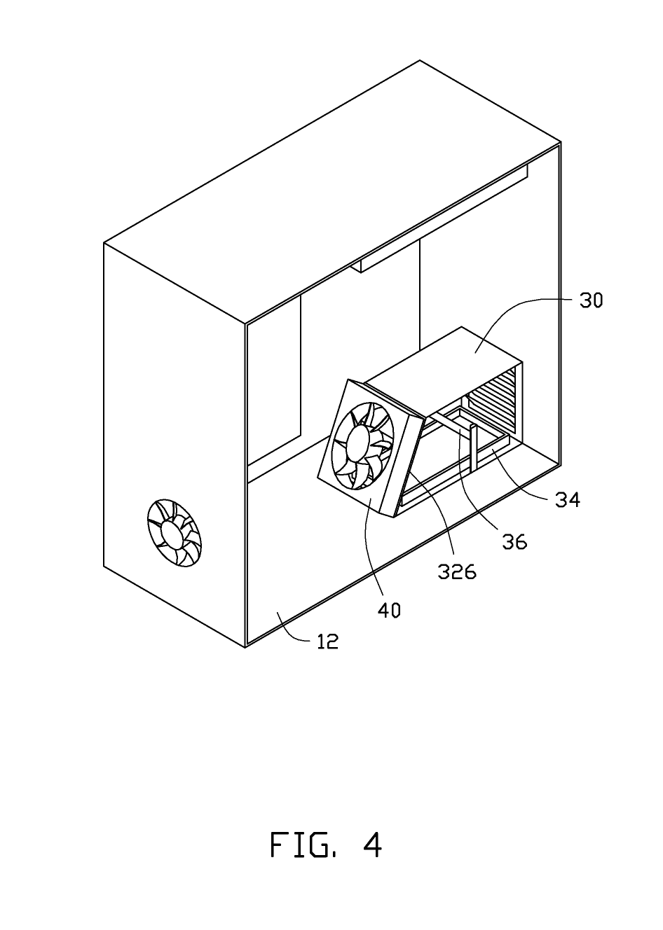

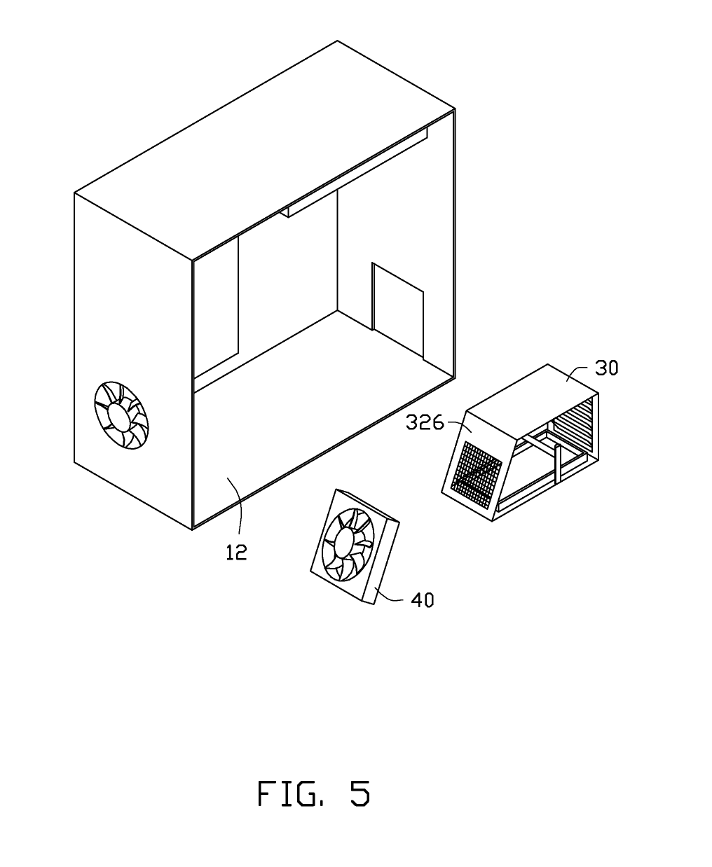

Referring to FIGS. 4 and 5, a bug sucking fan 40 may be mounted to the bug catching net 326 to improve the bugs catching efficiency. The bug sucking fan 40 also pulls air into the chassis 100 to form airflow in the cavity 327 to catch bugs. Further, when the heat dispersing fan 20 is not working or is turned off, the chassis 100 can still catch and kill bugs as long as the bug sucking fan 40 is working.

The exemplary heat dispersing fan 20 and/or the bug sucking fan 40 pull air into the cavity 327 through the passage 142 to form airflow to catch bugs, the bugs are then caught by the exemplary bug catching net 326, on which the bugs are dehydrated to death. As such, electric mosquito repellent is not required, thus harm to users is reduced.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A chassis having a bug killing property, comprising:
a housing;
a heat dispersing fan fastened in the housing; and
a bug killing assembly located in the housing, the bug killing assembly comprising:
a body defining a cavity; and
a bug catching net positioned in the cavity;
the heat dispersing fan pulling in air into the cavity to form airflow, the airflow sucking bugs into the cavity to be caught by the bug catching net.

2. The chassis as claimed in claim 1, wherein the housing comprises a bottom plate, a front plate, and a back plate, the front plate and the back plate are positioned at the two ends of the bottom plate and face each other, the front plate defines a passage which communicates with the cavity.

3. The chassis as claimed in claim 2, wherein the heat dispersing fan is fastened on the back plate and faces the passage.

4. The chassis as claimed in claim 2, wherein the body comprises a base board, a first side board, a second side board, a top board, and a door, the base board is fastened on the bottom plate, the first side board and the second side board are positioned at the two sides of the base board and face each other, the top board connects the ends of the first side board and the second side board away from the base board, the base board, first side board, second side board, and top board together define the cavity.

5. The chassis as claimed in claim 4, wherein the door is rotatably fastened to the second side board to open or close the passage.

6. The chassis as claimed in claim 5, wherein the door is a louvered door which allows air to pass through the passage when the door is closed.

7. The chassis as claimed in claim 4, wherein the bug killing assembly further comprises a drawer box for collecting dead bugs.

8. The chassis as claimed in claim 7, wherein the drawer box is located in the cavity and positioned on the base board.

9. The chassis as claimed in claim 4, wherein the bug killing assembly further comprises an ultraviolet tube which emits ultraviolet light to attract bugs into the cavity.

10. The chassis as claimed in claim 1, wherein the bug killing assembly further comprises a bug sucking fan which pulls in air into the cavity through the passage to form airflow, the bug sucking fan is fastened on the bug catching net.

11. A chassis having a bug killing assembly, comprising:
a housing; and
a heat dispersing fan fastened in the housing;
the bug killing assembly locating in the chassis, the bug killing assembly comprising a body, the body having a bug catching net, the heat dispersing fan sucking bugs to the bug catching net.

12. A chassis, comprising:
a housing; and
a bug killing assembly, the bug killing assembly located in the chassis, the bug killing assembly comprising a body, the body having a bug catching net which being mounted a bug sucking fan, the bug sucking fan sucking bugs to the bug catching net.
